(19) United States
(12) Patent Application Publication
(10) Pub. No.: US 2023/0375919 A1
(43) Pub. Date: Nov. 23, 2023

(54) PITCH AND ORIENTATION UNIFORMITY FOR NANOIMPRINT STAMP FORMATION

(71) Applicant: Applied Materials, Inc., Santa Clara, CA (US)

(72) Inventors: Jing JIANG, Santa Clara, CA (US); Kang LUO, San Jose, CA (US)

(21) Appl. No.: 18/320,683

(22) Filed: May 19, 2023

Related U.S. Application Data
(60) Provisional application No. 63/344,309, filed on May 20, 2022.

(51) Int. Cl. G03F 7/00; G02B 27/01

(52) U.S. Cl. CPC G03F 7/0002; G02B 27/0172; G03F 7/0005; G02B 2207/101; G02B 6/0038

(57) ABSTRACT

A system for nanoimprint lithography includes a master holder, a spacer, and a stamp support. The spacer supports the stamp support as a stamp material is cured to create a stamp. A method of forming an optical device using the nanoimprint lithography system with a spacer is provided. A system for the nanoimprint lithography may also include a master and a stamp support holder. The stamp support holder includes a plurality of projections defining a plurality of vacuum channels. The vacuum channels are in fluid communication with a vacuum source to support a stamp support as a stamp material is cured to create a stamp.

### CROSS-REFERENCE TO RELATED APPLICATIONS

This application claims benefit of U.S. provisional patent application Ser. No. 63/344,309, filed May 20, 2022, which is herein incorporated by reference.

### BACKGROUND

### Field

Embodiments of the present disclosure generally relate to optical devices. More specifically, embodiments described herein relate systems and methods of fabricating optical device structures.

### Description of the Related Art

Augmented reality enables an experience in which a user can still see through display lenses of glasses or other head-mounted display (HMD) devices to view a surrounding environment, yet also see images of virtual objects that are generated for display and appear as part of the environment. Augmented reality can include any type of input, such as audio and haptic inputs, as well as virtual images, graphics, and video that enhances or augments the environment that the user experiences. As an emerging technology, there are many challenges and design constraints with augmented reality.

One such challenge is displaying a virtual image overlaid on an ambient environment. Optical devices including waveguide combiners, such as augmented reality waveguide combiners, and flat optical devices, such as metasurfaces, are used to assist in overlaying images. Generated light is propagated through an optical device until the light exits the optical device and is overlaid on the ambient environment. Nanoimprint lithography and nanoimprint systems are utilized to form stamps with patterns of inverse structures, lithography patterns for hardmask etching, or the structures of the optical devices.

Accordingly, what is needed in the art are systems and methods of fabricating optical device structures.

### SUMMARY

In one embodiment, a system is shown. The system includes a master holder, a spacer, and a stamp support holder. The master holder operable to retain a master on a first portion of an upper surface of the master holder. The master has a master optical device pattern and master height from the upper surface of the master holder to an uppermost surface of the master when the master is retained. The spacer is disposed on a second portion of the upper surface of the master holder. The second portion is adjacent to the first portion. The spacer has a spacer height from the upper surface of the master holder to a top surface of the spacer. The spacer height is greater than the master height when the master is retained. The stamp support holder has a vacuum region operable to be in fluid communication with a vacuum source to retain a stamp support.

In another embodiment, a system is shown. The system includes a master holder and a stamp support. The master holder is operable to retain a master on a portion of an upper surface of the master holder. The master has a master optical device pattern of a plurality of master optical device regions. The stamp support holder has a plurality of projections. Adjacent projections of the plurality of projections define a plurality of vacuum channels with openings facing the master holder. The plurality of vacuum channels are operable to be in fluid communication with a vacuum source to retain a stamp support. Each projection of the plurality of projections corresponds to areas of the master optical device pattern with a respective master optical device region of the plurality of master optical devices regions.

In another embodiment, a method is shown. The method includes retaining a master on a first portion of an upper surface of a master holder, disposing a stamp material on an uppermost surface of the master, disposing a stamp support on the spacer and the stamp material, and curing the stamp material to form a cured stamp layer bonded to the stamp support. The master has a master optical device pattern. The stamp support is retained on a stamp support holder. The stamp support holder has a vacuum region. The cured stamp layer has a stamp pattern that is an inverse of the master optical device pattern.

### BRIEF DESCRIPTION OF THE DRAWINGS

So that the manner in which the above recited features of the present disclosure can be understood in detail, a more particular description of the disclosure, briefly summarized above, may be had by reference to embodiments, some of which are illustrated in the appended drawings. It is to be noted, however, that the appended drawings illustrate only exemplary embodiments and are therefore not to be considered limiting of its scope, and may admit to other equally effective embodiments.

FIG. 1A is a perspective frontal view of an optical device according to embodiments described herein.

FIG. 1B is a schematic top view of an optical device according to embodiments described herein.

FIG. 1C is a schematic cross-sectional view of a plurality of optical device structures according to embodiments described herein.

FIGS. 2A and 2B are schematic cross-sectional views of a system for nanoimprint lithography according to embodiments described herein.

FIG. 2C is a schematic cross-sectional view of a nanoimprint stamp according to embodiments described herein.

FIG. 3 is a flow diagram of a method of forming an optical device according to embodiments described herein.

FIG. 4A is a schematic cross-sectional view of a system for nanoimprint lithography according to embodiments described herein.

FIG. 4B are schematic bottom view of a stamp support holder according to embodiments described herein.

FIG. 4C is a schematic cross-sectional view of a nanoimprint stamp according to embodiments described herein.

FIG. 5 is a flow diagram of a method of forming an optical device according to embodiments described herein.

To facilitate understanding, identical reference numerals have been used, where possible, to designate identical elements that are common to the figures. It is contemplated that elements and features of one embodiment may be beneficially incorporated in other embodiments without further recitation.

### DETAILED DESCRIPTION

Embodiments of the present disclosure generally relate to optical devices. More specifically, embodiments described herein relate to systems and methods of fabricating optical device structures.

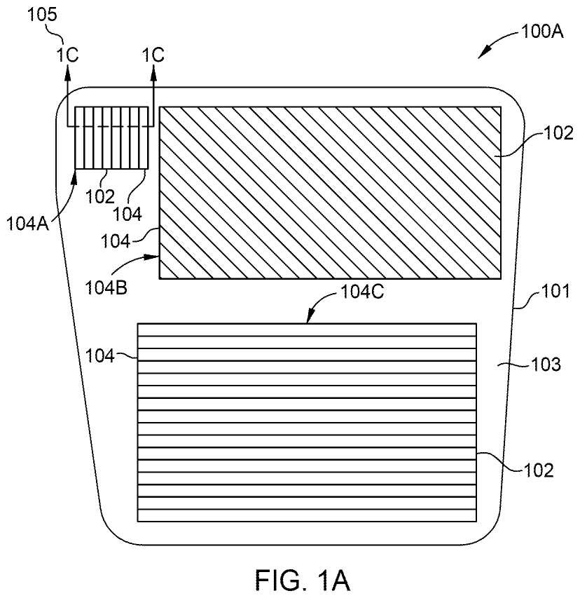

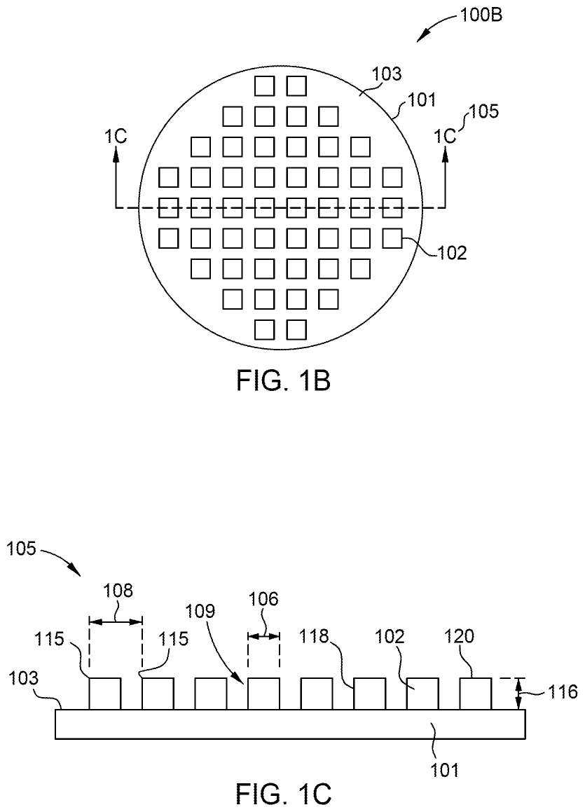

FIG. 1A is a perspective, frontal view of an optical device 100A. FIG. 1B is a schematic, top view of an optical device 100B. It is to be understood that the optical devices 100A and 100B described below are exemplary optical devices. In one embodiment, which can be combined with other embodiments described herein, the optical device 100A is a waveguide combiner, such as an augmented reality waveguide combiner. In another embodiment, which can be combined with other embodiments described herein, the optical device 100B is a flat optical device, such as a metasurface. The optical devices 100A and 100B include a plurality of optical device structures 102 disposed on a surface 103 of a substrate 101.

The optical device structures 102 may be nanostructures having sub-micron dimensions, e.g., nanosized dimensions. In one embodiment, which can be combined with other embodiments described herein, regions of the optical device structures 102 correspond to one or more gratings 104, such as a first grating 104A, a second grating 104B, and a third grating 104C. In another embodiment, which can combined with other embodiments described herein, the optical device 100A is a waveguide combiner that includes at least the first grating 104A corresponding to an input coupling grating and the third grating 104C corresponding to an output coupling grating. The waveguide combiner, according to the embodiment, which can be combined with other embodiments described herein, includes the second grating 104B corresponding to an intermediate grating. While FIG. 1B depicts the optical device structures 102 as having square or rectangular shaped cross-sections, the cross-sections of the optical device structures 102 may have other shapes including, but not limited to, circular, triangular, elliptical, regular polygonal, irregular polygonal, and/or irregular shaped cross-sections. In some embodiments, which can be combined with other embodiments described herein, the cross-sections of the plurality of optical device structures 102 have different shaped cross-sections. In other embodiments, which can be combined with other embodiments described herein, the cross-sections of the optical device structures 102 have cross-sections with substantially the same shape.

FIG. 1C is a schematic cross-sectional view of a plurality of optical device structures 102. FIG. 1C is a portion 105 of the optical device 100A or the optical device 100B. The portion 105 of the optical devices 100A and 100B include the plurality of optical device structures 102 disposed on a surface 103 of a substrate 101. The portion 105 may correspond to one or more gratings 104. Each optical device structure of the plurality of optical device structures 102 has an optical device structure width 106. In one embodiment, which may be combined with other embodiments described herein, the optical device structure width 106 is less than 1 micrometer (μm) and corresponds to the width or the diameter of each optical device structure 102, depending on the cross-section of the optical device structure 102. In one embodiment, which can be combined with other embodiments described herein, at least one optical device structure width 106 may be different from another optical device structure width 106. In another embodiment, which can be combined with other embodiments described herein, each optical device structure width 106 of the plurality of optical device structures 102 is substantially equal to each other.

Each optical device structure 102 of the plurality of optical device structures 102 has a sidewall 118 having a height 116. The height 116 is the distance from the surface 103 of the substrate to a top surface 120 of each optical device structure 102. In one embodiment, which can be combined with other embodiments described herein, at least one height 116 of the plurality of optical device structures 102 is different from the height 116 of an adjacent optical device structures 102. In another embodiment, which can be combined with other embodiments described herein, each height 116 of the plurality of optical device structures 102 is substantially equal to the adjacent optical device structures 102.

The optical device structures 102 are formed from a device material. In some embodiments, which can be combined with other embodiments described herein, the device material includes, but is not limited to, one or more of silicon oxycarbide (SiOC), titanium dioxide (TiO₂), silicon dioxide (SiO₂), vanadium (IV) oxide (VOx), aluminum oxide (Al₂O₃), aluminum-doped zinc oxide (AZO), indium tin oxide (ITO), tin dioxide (SnO₂), zinc oxide (ZnO), tantalum pentoxide (Ta₂O₅), silicon nitride (Si₃N₄), zirconium dioxide (ZrO₂), niobium oxide (Nb₂O₅), cadmium stannate (Cd₂SnO₄), silicon carbide (SiC), silicon carbon-nitride (SiCN) containing materials, or combinations thereof.

The substrate 101 may also be selected to transmit a suitable amount of light of a desired wavelength or wavelength range, such as one or more wavelengths from about 100 to about 3000 nanometers. Without limitation, in some embodiments, the substrate 101 is configured such that the substrate 101 transmits greater than or equal to about 50% to about 100%, of an infrared to ultraviolet region of the light spectrum. The substrate 101 may be formed from any suitable material, provided that the substrate 101 can adequately transmit light in a desired wavelength or wavelength range and can serve as an adequate support for the optical devices 100A and 1006 described herein. In some embodiments, which can be combined with other embodiments described herein, the material of substrate 101 has a refractive index that is relatively low, as compared to the refractive index of the device material. Substrate selection may include substrates of any suitable material, including, but not limited to, amorphous dielectrics, non-amorphous dielectrics, crystalline dielectrics, silicon oxide, polymers, or combinations thereof. In some embodiments, which may be combined with other embodiments described herein, the substrate 101 includes a transparent material. In one embodiment, which may be combined with other embodiments described herein, the substrate 101 is transparent with absorption coefficient smaller than 0.001. Suitable examples may include, but are not limited to, an oxide, sulfide, phosphide, telluride, silicon carbide (SiC), or combinations thereof. In one example, the substrate 101 includes silicon (Si), silicon dioxide (SiO₂), germanium (Ge), silicon germanium (SiGe), InP, GaAs, GaN, fused silica, quartz, sapphire, and high-index transparent materials such as glass, or combinations thereof.

The optical device structures 102 include a critical dimension 108, i.e., a pitch, defined as the distance from a leading edge 115 to the leading edge 115 of adjacent optical device structures 102. As shown in FIG. 1C, the critical dimension 108 of each of the adjacent optical device structure 102 is substantially equal to each other. An optical device trench 109 is defined by each pair of adjacent optical device structures 102 of the plurality of optical device structures 102 and the surface 103 of the substrate 101. The width of each optical device trench 109 corresponds to the critical dimension 108. The height of each optical device trench 109 corresponds to the height 116 of the adjacent optical device structures 102.

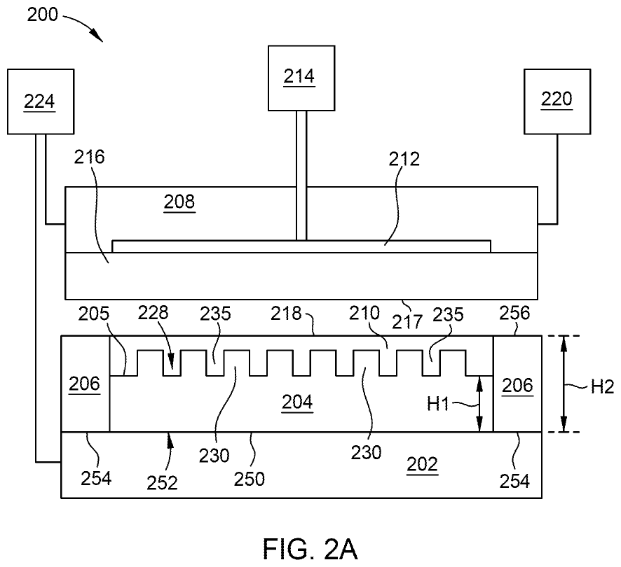

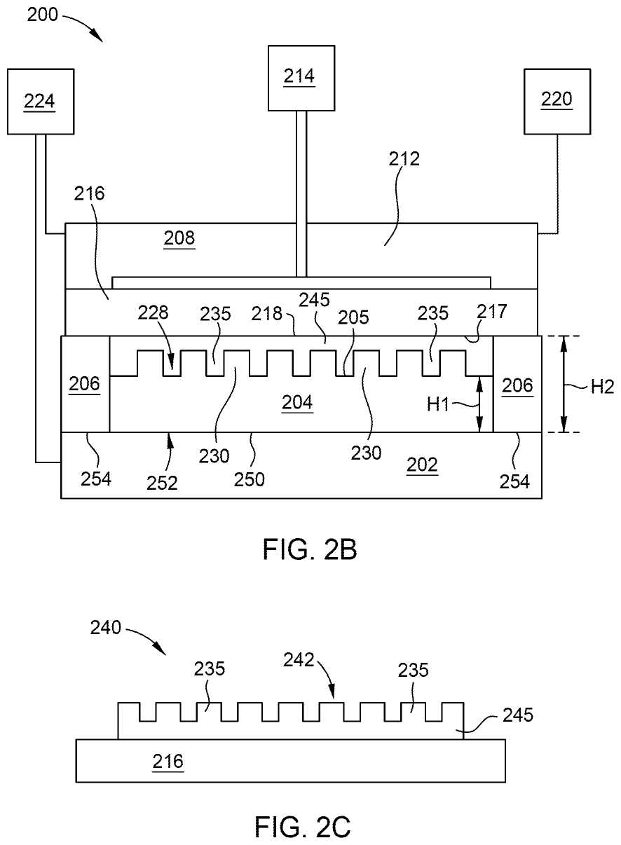

FIGS. 2A and 2B are schematic cross-sectional views of a system 200 for nanoimprint lithography. The system 200 includes a master holder 202, a master 204, a spacer 206, a stamp support holder 208, an actuator 220, and a controller 224 capable of operating the system 200. The master holder 202 is operable to retain the master 204 on a first portion 250 of an upper surface 252 of the master holder 202. The master 204 is configured to have a master optical device pattern 228 characterized by a plurality of master structures 230. The plurality of master structures 430 define the critical dimension 108 of the optical device structure 102. The plurality of master structures 230 are sized and shaped to match the optical device structures 102. The master optical device pattern 228 may correspond to an optical device structures 102 of the waveguide combiner such as FIG. 1A or optical device structures 102 of a flat optical device such as FIG. 1B. The master 204 further has a master height H1 from the upper surface 252 of the master holder 202 to an uppermost surface 205 of the master 204 when the master 204 is retained.

The spacer 206 is adjacent to the master 204. In one embodiment, the spacer 206 surrounds the master 204. In another embodiment, the master 204 is adjacent to a first spacer and a second spacer. The spacer 206 is disposed on a second portion 254 of the upper surface 252 of the master holder 202. The second portion 254 surrounds the first portion 250 and has a spacer height H2 from the upper surface 252 of the master holder 202 to a top surface 256 of the spacer 206. The spacer height H2 is greater than the master height H1 when the master 204 is retained.

When a stamp material 210 is disposed on the master 204, the spacer 206 is adjacent to the master 204 and the stamp material 210. In one embodiment, the spacer 206 surrounds the master 204 and the stamp material 210. In another embodiment, the master 204 is adjacent to a first spacer 206 and a second spacer 206. The stamp material 210, in one embodiment, is a polydimethylsiloxane (PDMS). The stamp material 210 is deposited on the master 204. The stamp material 210 may be poured onto the master 204 or may be spun onto the master 204. A top surface 218 of the stamp material 210 may be aligned with or above the top surface 256 of the spacer 206.

The stamp support holder 208 is further configured to include a vacuum region 212. The vacuum region is operable to be in fluid communication with a vacuum source 214 to retain a stamp support 216 to the stamp support holder 208. The vacuum source is used to apply a vacuum force between the stamp support holder 208 and the stamp support 216 to operably secure the stamp support 216 to the stamp support holder 208. The stamp support 216, in one embodiment, is a glass structure. Referring to FIG. 2A, the stamp support 216 is in spaced apart relation to the stamp material 210. The actuator 220 is operable to contact the top surface 217 of the stamp support 216 and the top surface 256 of the spacer 206. When in contact with the spacer 206, the stamp support 216 also contacts the stamp material 210. Referring to FIG. 2B, the actuator 220 has moved the stamp support 216 and the stamp support holder 208 towards the stamp material 210 such that the stamp support 216 is in contact with the top surface 218 of the stamp material 210 and the top surface 256 of the spacer 206. The controller 224 of the system 200 is in communication with the master holder 202, the stamp support holder 208, and the actuator 220. The controller 224 is also operable to cure the stamp material 210 into a cured stamp layer 245 and bond the cured stamp layer 245 to the stamp support 216, thereby forming a stamp 240 as seen in FIG. 2C. The controller 224 can cure the stamp material 210 through the use of heat, light, or other means. The cured stamp material 245 is configured to have a stamp pattern 242 including a plurality of stamp structures 235 that is an inverse of the master optical device pattern 228.

The spacer 206 supports the stamp support 216. The support provided by the spacer 206 supports the edges of the stamp support 216 to prevent bowing. Bowing may create nonuniformity in the pitch of the stamp 240. The support from the spacer 206 reduces bowing resulting in substantially uniform pitch 108 of the inverse optical device structures 102 of the stamp 240.

After curing the stamp material 210 to create the cured stamp layer 245 and bonding the cured stamp layer 245 to the stamp support 216 to create the stamp 240, the actuator 220 is configured to move the stamp support holder 208 away from the master 204 such that the cured stamp material 245 is no longer disposed on the master 204. The vacuum source 214 stops providing the vacuum to the vacuum region 212, thereby releasing the stamp support 216 from the stamp support holder 208. Once released, the stamp 240 can be removed from the system 200 for use in nanoimprinting applications.

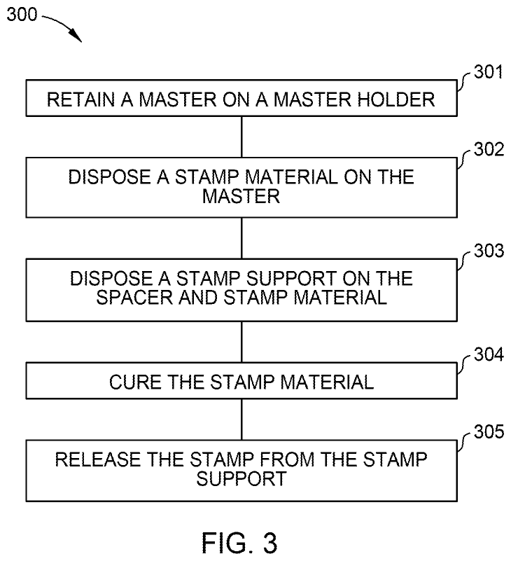

FIG. 3 is a flow diagram of a method 300 for forming the stamp 240 as shown in FIG. 2C. The method 300 utilizes the system shown in FIGS. 2A and 2B. At operation 301, a master 204 is retained on a master holder 202. The master 204 is retained on a first portion 250 of an upper surface 252 of the master holder 202. The master 204 has a master optical device pattern 228 pattern thereupon and is adjacent to a spacer 206. In one embodiment, the spacer 206 surrounds the master 204 and the stamp material 210. In another embodiment, the master 204 is adjacent to a first spacer and a second spacer. The spacer 206 is disposed on a second portion 254 of the upper surface 252 of the master holder 202.

At operation 302, a stamp material 210 is disposed on the master 204. The stamp material 210 may be disposed on an uppermost surface 205 of the master 204. The stamp material 210 has a top surface 218 aligned with or above the top surface 256 of the spacer 206.

At operation 303, a stamp support 216 is disposed on the spacer 206 and the stamp material 210. The stamp support 216 is configured to be retained by a stamp support holder 208 and held in spaced apart relation from the stamp material 210. A vacuum is applied in a vacuum region 212 of the stamp support holder 208 to secure the stamp support 216 to the stamp support holder 208. The vacuum is generated using a vacuum source 214. An actuator 220 moves the stamp support holder 208 towards the stamp material 210, thereby disposing the stamp support 216 on the spacer 206 and the stamp material 210.

At operation 304, the stamp material 210 is cured. The stamp material 210 is cured to form a cured stamp layer 245 bonded to the stamp support 216. The cured stamp material layer 245 and stamp support 216 form a stamp 240. The cured stamp layer 245 is configured to have a stamp pattern 242 including a plurality of stamp structures 235 that is an inverse of the master optical device pattern 228. In one embodiment, a bonding layer is disposed on the stamp support 216 and is coupled to the cured stamp layer 245 to promote bonding between the stamp support 216 and the cured stamp layer 245.

At operation 305, the stamp 240 is released from the master 204. The actuator moves the stamp support holder 208 away from the master 204. The stamp 240 remains retained on the stamp support holder 208 by the stamp support 216. The vacuum being generated by the vacuum source 214 is discontinued, releasing the stamp support 216 from the stamp support holder 208, releasing the stamp 240 from the master 204.

The stamp may be used to for nanoimprint lithography (NIL) of optical device materials. In one example, a nanoimprint resist of an optical device material is disposed on a portion of a substrate and imprinted by the stamp 240 to create the optical device pattern of FIG. 1A or 1B. The nanoimprint resist is cured to stabilize the optical device structure 102, and the stamp 240 is released.

In another example, the stamp 240 is used to pattern a nanoimprint material disposed over the hard mask. The nanoimprint material is disposed on a portion of a hardmask disposed over a substrate and imprinted by the stamp 240 to create the optical device pattern of FIG. 1A or 1B. The hardmask is etched according to the optical device pattern and then the substrate or an optical device material deposited thereover is etched. The stamp 240 is an inverse of master optical device pattern 228 and the optical device pattern to be formed.

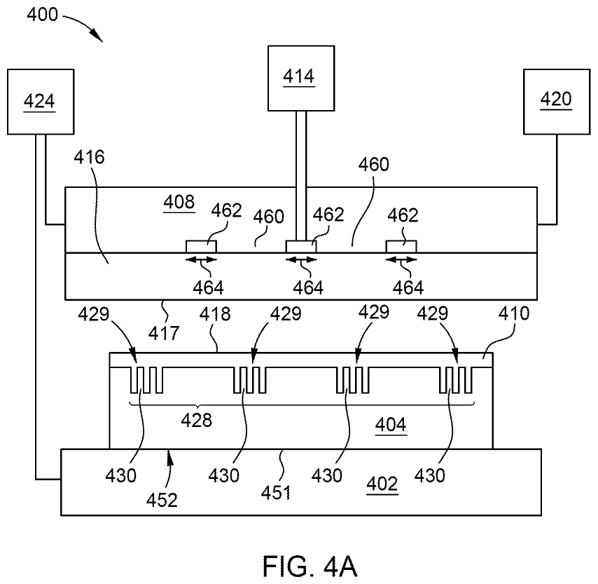

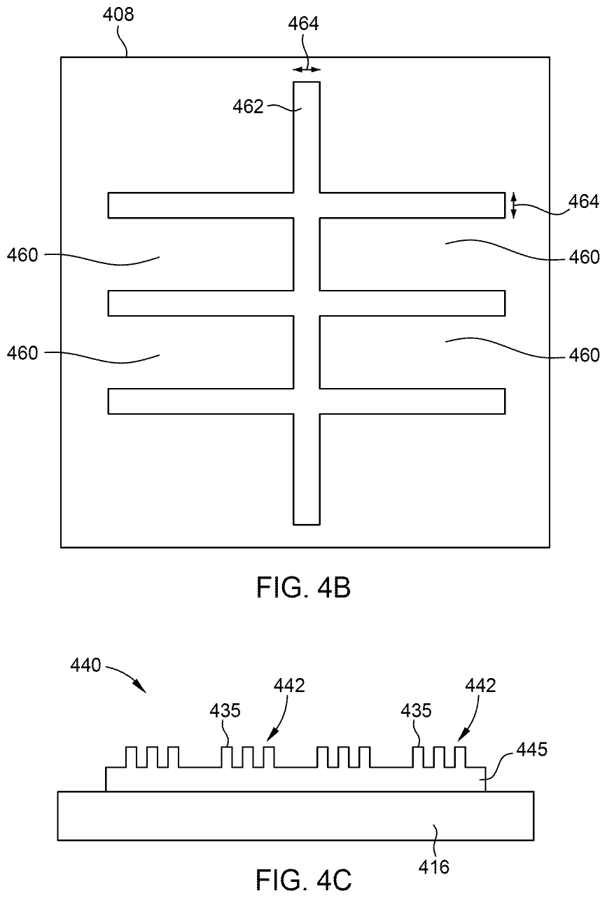

FIG. 4A is a schematic cross-sectional view of a system 400 for nanoimprint lithography. The system 400 includes a master holder 402, a master 404, a stamp support holder 408, an actuator 420, and a controller 424 capable of operating the system 200. The master holder 402 is operable to retain a master 404 on a portion 451 of an upper surface 452 of the master holder 402. The master 404 is configured to have a master optical device pattern 428 of a plurality of master optical device regions 429. The master optical device pattern 419 is characterized by a plurality of master structures 430. The plurality of master structures 430 are sized and shaped to match the optical device structures 102. The plurality of master structures 430 define the critical dimension 108 of the optical device structure 102. The master optical device regions 429 may correspond to an optical device structures 102 of the waveguide combiner such as FIG. 1A or optical device structures 102 of a flat optical device such as FIG. 1B.

When a stamp material 410 is disposed on the master 404, the stamp material 410 may be poured onto the master 404 or may be spun onto the master 404. The stamp material 410, in one embodiment, is a polydimethylsiloxane (PDMS). The stamp material 410 is deposited on the master 404.

The stamp support holder 408 is configured to have a plurality of projections 460. Adjacent projections 460 of the plurality of projections 460 define a plurality of vacuum channels 462 with openings 464 facing the master holder 402. The plurality of vacuum channels 462 are operable to be in fluid communication with a vacuum source 414 to retain a stamp support 416. The vacuum source 414 is used to apply a vacuum force between the stamp support holder 408 and a stamp support 416 to operably secure the stamp support 416 to the stamp support holder 408. The stamp support 416, in one embodiment, is a glass structure.

The stamp support 416 is in spaced apart relation to the stamp material 410. The actuator 420 is operable to contact a top surface 417 of the stamp support 416 with the stamp material 410. Referring to FIG. 4B, the actuator 420 has moved the stamp support 416 and the stamp support holder 408 towards the stamp material 410 such that the stamp support 416 is in contact with the top surface 418 of the stamp material 410. The controller 424 of the system 400 is in communication with the master holder 402, the stamp support holder 408, and the actuator 420. The controller 424 is operable to instruct the master holder 402 to retain the master 404, to instruct the stamp support holder 408 to retain the stamp support 416, and to instruct the actuator 420 to move the stamp support 416 to contact the stamp material 410. The controller 424 is also operable to cure the stamp material 410 into a cured stamp layer 445 and bond the cured stamp layer 445 to the stamp support 416, thereby forming a stamp 440 as seen in FIG. 4C. The controller 424 can cure the stamp material 410 through the use of heat, light, or other means. The cured stamp layer 445 is configured to have a stamp pattern 442 including a plurality of stamp structures 435 that is an inverse of the master optical device pattern 428.

Each projection 460 of the plurality of projections 460 corresponds to areas of the master optical device pattern 428 with a respective master optical device region 429 of the plurality of master optical device regions 429, while the vacuum channels 462 are defined in between the plurality of optical device regions 429. The vacuum channels 462 support the stamp support 416. The support provided by the vacuum channels 462 supports the edges of the stamp support 416 to prevent bowing. Bowing may create nonuniformity in the pitch of the stamp 440 and subsequently the optical device structures 102. The support from the stamp support holder 408 reduces bowing resulting in substantially uniform pitch 108 of the inverse optical device structures 102 of the stamp 440.

Referring to FIG. 4C, a stamp 440 is shown. After curing the stamp material 410 to create the cured stamp layer 445 and bonding the cured stamp layer 445 to the stamp support 416 to create the stamp 440, the actuator 420 is configured to move the stamp support holder 408 away from the master 404 such that the cured stamp layer 445 is not disposed on the master 404. The stamp 440 includes the cured stamp layer 445 and the stamp support 416. The cured stamp layer 445 further includes the stamp patterns 442 which are the inverse of the master optical device pattern 428. The vacuum source 414 stops providing the vacuum to the vacuum region, thereby releasing the stamp support 416 from the stamp support holder 408. Once released, the stamp 440 can be removed from the system 400 for use in nanoimprinting applications.

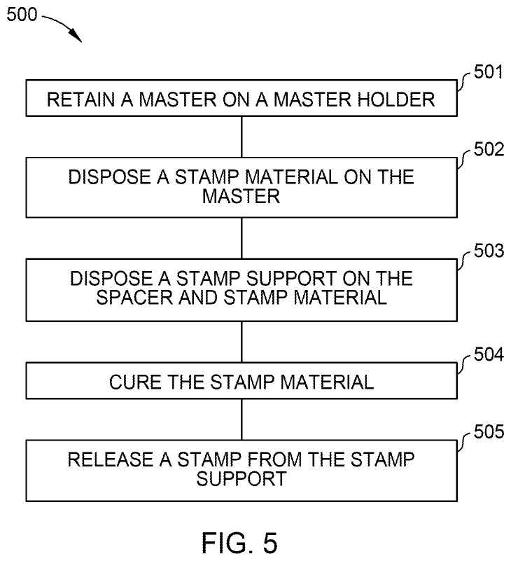

FIG. 5 is a flow diagram of a method 500 for forming the stamp 440 as shown in FIG. 4C. The method 500 utilizes the system shown in FIGS. 4A and 4B. At operation 501, a master 404 is retained on a master holder 402. The master 403 may be retained on an upper surface 452 of the master holder 402. The master holder 402 is operable to retain the master 404 on a portion 451 of the upper surface 452 of the master holder 402. The master holder 402 further has a master optical device pattern 428 of a plurality of master optical device regions 429. At operation 502, a stamp material 410 is disposed on the master 404. The stamp material 410 may be disposed on an uppermost surface 405 of the master 404.

At operation 503, a stamp support 416 is disposed on the stamp material 410. The stamp support 416 is retained on a stamp support holder 408. The stamp support 416 is initially configured to be retained by a stamp support holder 408 in spaced apart relation from the stamp material 410. Each projection 460 of the plurality of projections 460 corresponds to areas of the master optical device pattern 428 with a respective master optical device region 429 of the plurality of master optical device regions 429. The vacuum is generated using a vacuum source 414. An actuator 420 moves the stamp support holder 408 towards the stamp material 410, thereby disposing the stamp support 416 on a top surface 418 of the stamp material 410.

At operation 504, the stamp material 410 is cured. The cured stamp material 410 forms a cured stamp layer 445 bonded to the stamp support 416. The cured stamp layer 445 and the stamp support 416 form a stamp 440. The cured stamp layer 445 has a stamp pattern 442 that is an inverse of the master optical device pattern 428. In one embodiment, a bonding layer is disposed on the stamp support 416 and is coupled to the cured stamp layer 445 to promote bonding between the stamp support 416 and the cured stamp layer 445.

At operation 505, the stamp 440 is released from the master 404. The actuator 420 moves the stamp support holder 408 away from the master 404. The stamp 440 remains retained on the stamp support holder 408 by the stamp support 416. The vacuum being generated by the vacuum source 414 is discontinued, releasing the stamp support 416 from the stamp support holder 408, releasing the stamp 440 from the master 404.

The stamp may be used to for nanoimprint lithography (NIL) of optical device materials, where a nanoimprint resist is disposed on a portion of a substrate and imprinted by the stamp 440 to create the optical device pattern of FIG. 1A or 1B. The nanoimprint resist is cured to stabilize the optical device structure 102, and the stamp 440 is released. The stamp 440 may also be used to pattern an imprint material disposed over the hard mask. A nanoimprint material is disposed on a portion of a hardmask disposed on a substrate and imprinted by the stamp 440 to create the optical device pattern. The hardmask is etched according to the optical device pattern and then the substrate 101 is etched. The stamp 440 is an inverse of master optical device pattern 428 and the optical device pattern to be formed in FIG. 1A or 1B. The master optical device regions 429 can be a grating or areas of the flat optical device with the optical device structures, while the vacuum channels 462 are the areas without optical device patterns.

In summation, systems and methods of fabricating optical device structures are described herein. In one embodiment, a system for nanoimprint lithography includes a master holder, a spacer, and a stamp support. The spacer supports the stamp support as a stamp material is cured to create a stamp. In another embodiment, a system for the nanoimprint lithography may also include a master and a stamp support holder. The stamp support holder includes a plurality of projections defining a plurality of vacuum channels. The vacuum channels are in fluid communication with a vacuum source to support a stamp support as a stamp material is cured to create a stamp. A method of forming an optical device using the nanoimprint lithography systems is provided.

While the foregoing is directed to embodiments of the present disclosure, other and further embodiments of the disclosure may be devised without departing from the basic scope thereof, and the scope thereof is determined by the claims that follow.

What is claimed is:

1. A system, comprising:
a master holder, the master holder operable to retain a master on a first portion of an upper surface of the master holder, the master having a master optical device pattern and master height from the upper surface of the master holder to an uppermost surface of the master when the master is retained;
a spacer disposed on a second portion of the upper surface of the master holder, the second portion adjacent to the first portion and having a spacer height from the upper surface of the master holder to a top surface of the spacer, wherein the spacer height is greater than the master height when the master is retained; and
a stamp support holder having a vacuum region operable to be in fluid communication with a vacuum source to retain a stamp support.

2. The system of claim 1, further comprising an actuator coupled to the stamp support, the actuator operable to contact the stamp support with the spacer.

3. The system of claim 2, further comprising a controller in communication with the master holder, the stamp support holder, and the actuator, the controller is operable to:
instruct the master holder to retain the master;
instruct the stamp support holder to retain the stamp support, the stamp support being retained on a stamp support holder having a vacuum region, a vacuum source provides vacuum to the vacuum region in fluid communication with the vacuum source to retain the stamp support; and
instruct the actuator to move the stamp support to contact the spacer.

4. The system of claim 3, wherein the controller is further operable to:
instruct the system to cure a stamp material into a cured stamp layer.

5. The system of claim 1, wherein a plurality of master structures of the master optical device pattern defines a critical dimension.

6. The system of claim 1, wherein the spacer surrounds the master.

7. The system of claim 1, wherein the master is adjacent to a first spacer and a second spacer.

8. A system, comprising:
a master holder, the master holder operable to retain a master on a portion of an upper surface of the master holder, the master having a master optical device pattern of a plurality of master optical device regions; and
a stamp support holder having a plurality of projections, adjacent projections of the plurality of projections defining a plurality of vacuum channels with openings facing the master holder, the plurality of vacuum channels operable to be in fluid communication with a vacuum source to retain a stamp support, each projection of the plurality of projections corresponding to areas of the master optical device pattern with a respective master optical device region of the plurality of master optical devices regions.

9. The system of claim 8, further comprising an actuator coupled to the stamp support, the actuator operable to contact the stamp support with the spacer.

10. The system of claim 9, further comprising a controller in communication with the master holder, the stamp holder, and the actuator, the controller is operable to:
instruct the master holder to retain the master;
instruct the stamp support holder to retain the stamp support, the stamp support being retained on a stamp support holder having a plurality of projections defining a plurality of vacuum channels, a vacuum source provides vacuum to the plurality of vacuum channels in fluid communication with the vacuum source to retain the stamp support; and
instruct the actuator to move the stamp support to contact the spacer.

11. The system of claim 10, wherein the controller is further operable to:
instruct the system to cure a stamp material disposed on the master into a cured stamp layer.

12. The system of claim 8, wherein the master optical device pattern includes a plurality of master structures.

13. The system of claim 12, wherein the master structures define a critical dimension.

14. A method, comprising:
retaining a master on a first portion of an upper surface of a master holder, the master having a master optical device pattern;
disposing a stamp material on an uppermost surface of the master;
disposing a stamp support on the spacer and the stamp material, the stamp support being retained on a stamp support holder, the stamp support holder having a vacuum region; and
curing the stamp material to form a cured stamp layer bonded to the stamp support, the cured stamp layer having a stamp pattern that is an inverse of the master optical device pattern.

15. The method of claim 14, further comprising applying a vacuum in a vacuum region of a stamp support holder to secure the stamp support to the stamp support holder.

16. The method of claim 15, wherein the vacuum region comprises a plurality of vacuum channels, wherein the plurality of vacuum channels are in fluid connection to a vacuum source to retain the stamp support.

17. The method of claim 16, wherein the stamp support includes a plurality of projection, each projection of the plurality of projections defining the plurality of vacuum channels and corresponding to areas of the master optical device pattern with a respective master optical device region of the plurality of master optical devices regions.

18. The method of claim 14, wherein the master is adjacent to a spacer disposed on a second portion of the upper surface of the master holder.

19. The method of claim 15, wherein the stamp material has a top surface aligned with or above a top surface of the spacer

20. The method of claim 14, wherein a bonding layer is disposed on the stamp support and is coupled to the cured stamp layer.
